(19) United States
(12) Patent Application Publication
(10) Pub. No.: US 2010/0005372 A1
(43) Pub. Date: Jan. 7, 2010

(54) METHOD AND APPARATUS FOR IMPROVING TRELLIS DECODING

(75) Inventors: Peter R. Dent, Irthingborough (GB); Eric Biscondi, Opio (FR); David Hoyle, Austin, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/496,527

(22) Filed: Jul. 1, 2009

Related U.S. Application Data
(60) Provisional application No. 61/077,756, filed on Jul. 2, 2008.

(51) Int. Cl. H03M 13/23; G06F 11/10

(52) U.S. Cl. 714/795; 714/E11.032

(57) ABSTRACT

A digital signal processor for decoding Trellis based channel encoding stages based on radix-4 stages comprising means for rearranging the input and output data in Radix-4 Viterbi decoding to make inter-stage Trellis data movement suitable for use in the digital signal processor.

### CROSS-REFERENCE TO RELATED APPLICATIONS

This application claims benefit of U.S. provisional patent application Ser. No. 61/077,756, filed Jul. 2, 2008, which is herein incorporated by reference.

### BACKGROUND OF THE INVENTION

1. Field of the Invention

Embodiments of the present invention generally relate to a method and apparatus for improving Trellis decoding.

2. Description of the Related Art

The trellis diagram of FIG. 1 helps explain the Viterbi algorithm. FIG. 1 shows the trellis diagram for our example rate ½K=3 convolutional encoder, for a 15-bit message.

The four possible states of the encoder are depicted as four rows of horizontal dots. There is one column of four dots for the initial state of the encoder and one for each time instant during the message. For a 15-bit message with two encoder memory flushing bits, there are 17 time instants in addition to t=0, which represents the initial condition of the encoder. The solid lines connecting dots in the diagram represent state transitions when the input bit is a one. The dotted lines represent state transitions when the input bit is a zero. Notice the correspondence between the arrows in the trellis diagram and the state transition table. Also, since the initial condition of the encoder is State 002, and the two memory flushing bits are zeroes, the arrows start out at State 002 and end up at the same state.

The FIG. 2 shows the states of the trellis that are actually reached during the encoding of our example 15-bit message.

The encoder input bits and output symbols are shown at the bottom of the diagram. Notice the correspondence between the encoder output symbols and the output table. Let's look at that in more detail, using the expanded version of the transition between one time instant to the next, as shown in FIG. 3.

The two-bit numbers labeling the lines are the corresponding convolutional encoder channel symbol outputs. Remember that dotted lines represent cases where the encoder input is a zero, and solid lines represent cases where the encoder input is a one. (In the figure above, the two-bit binary numbers labeling dotted lines are on the left, and the two-bit binary numbers labeling solid lines are on the right.)

### SUMMARY OF THE INVENTION

Embodiment of the present invention relates to a digital signal processor for decoding Trellis based channel encoding stages based on radix-4 stages comprising means for rearranging the input and output data in Radix-4 Viterbi decoding to make inter-stage Trellis data movement suitable for use in the digital signal processor.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1. is a trellis diagram;

FIG. 2 shows states of the trellis;

FIG. 3 shows an expanded version of transition between one time instant to another;

FIG. 4 is an exemplary generic flow chart for a method of decoding;

FIG. 5. is an exemplary diagram depicting a method for reversing the addition and subtraction;

FIG. 6 shows an exemplary diagram depicting a method for perform parallelism;

FIG. 7 is a depiction often used for a trellis stage; and

FIG. 8 depicts a register ordering for bringing in inner and outer loops.

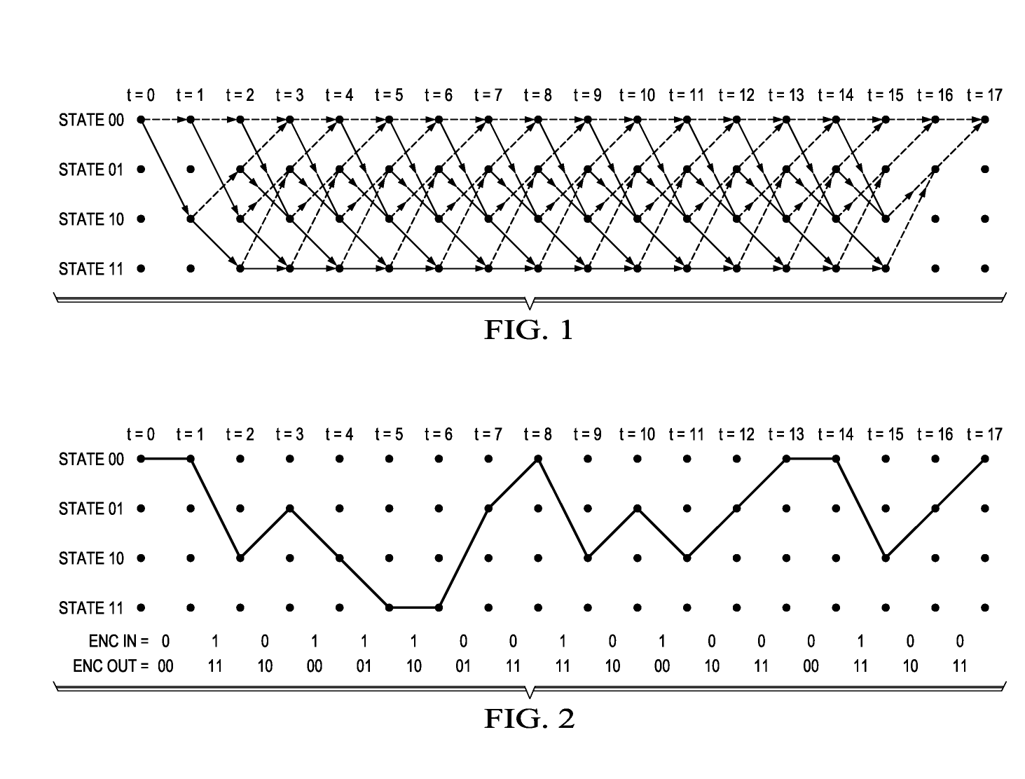

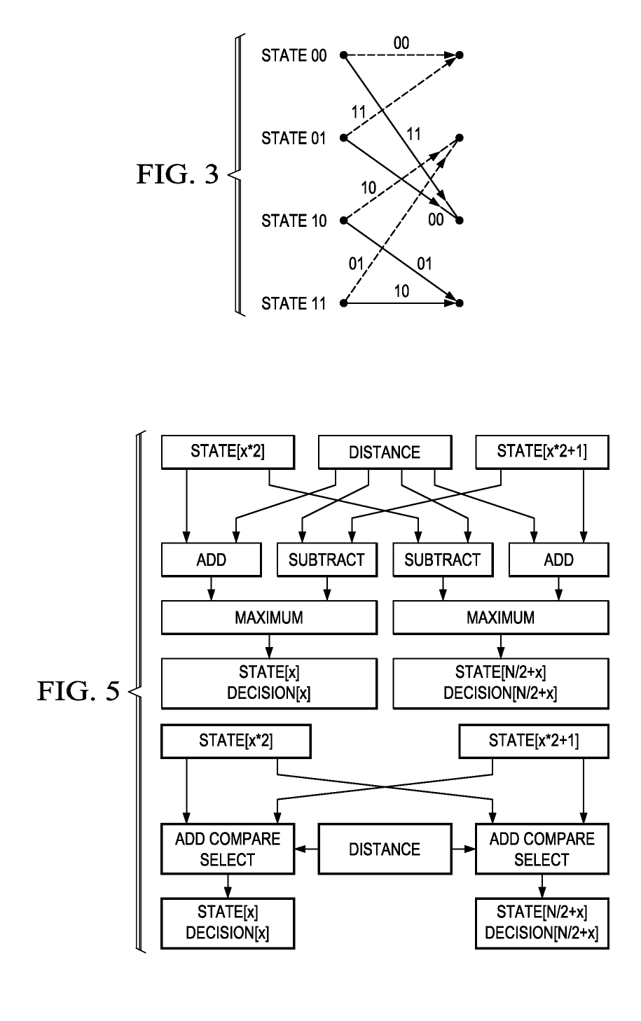

### DETAILED DESCRIPTION

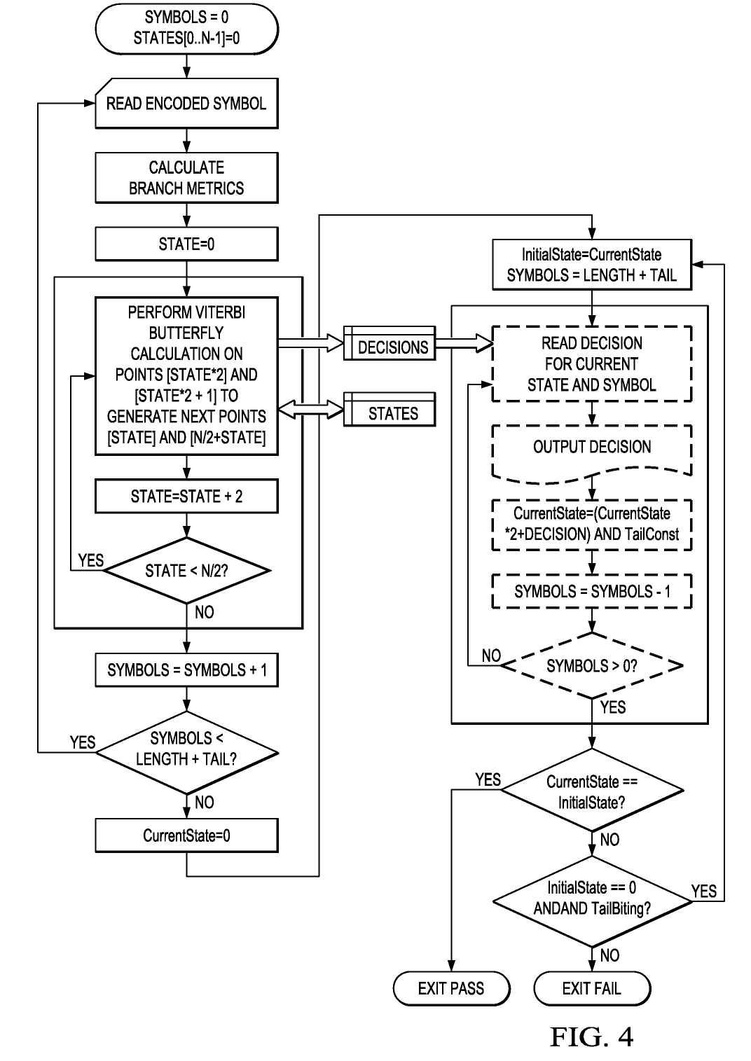

The decoding algorithm consists of a series of 2 loops the first of which may contain an inner loop. The second loop maybe a single loop which may be repeated a second time in some versions of the algorithm. The generic flow chart is shown in FIG. 4. (=, ==, &, && have their ANSI-C definitions).

However the core of the algorithm consists of the two loops highlighted in blue and green. The loop 1 is commonly called the “forward” loop and the loop 2 the “trace-back” loop. There are variations on the InitialState and CurrentState variables but these do not concern this invention, there is also a variation where the initial state is based on the input data, this is known as tail-biting, but again this does not concern this invention. Data is typically encoded with a coder or length 6 or 8.
1). If data is coded with a coder of length 6. N=64, Tail=6 TailConst=63.
2). If data is coded with a coder of length 8. N=256, Tail=8 TailConst=255.
3). In all cases Symbols is the length of the original data encoded in bits.

The Viterbi Butterfly algorithm works on 2 sequential states at a time adding a pre-determined “distance” to 1 value whilst subtracting it from the other value. It then selects the maximum of the two results and outputs a decision bit as to which was the maximum. It makes a second output for a second maximum and a second decision by reversing the addition and subtraction, as shown in FIG. 5. The complete form is shown on the left, whilst a simplified representation commonly known as the “Radix-2 Viterbi Butterfly” is shown on the right.

Traditionally in a DSP this building block is implemented with traditional separate add, sub, max and cmp instructions. In later DSP's with the advent of SIMD (Single Instruction Multiple Data) it became possible to do some parallelism by either paralleling the adds, subs, maxs and cmps into add2's sub2's max2's and cmp2's or by creating additional instructions like addsub to pair an add or subtract or even ACS (add, compare select) instructions, but the finite data-word length and the need for around 16 bits of precision has limited the ability of instructions to perform bigger blocks.

With the advent of wider data paths and registers in the newest processors, and TI's proposed proton accelerator which has 64-bit registers, and 128-bit register pairs it is obvious that more channels can be paralleled. At 16 bits per state variable and 128-bits per register it is now possible to input 8 states at a time. The obvious extension is therefore to parallel up 4 “butterflys”.

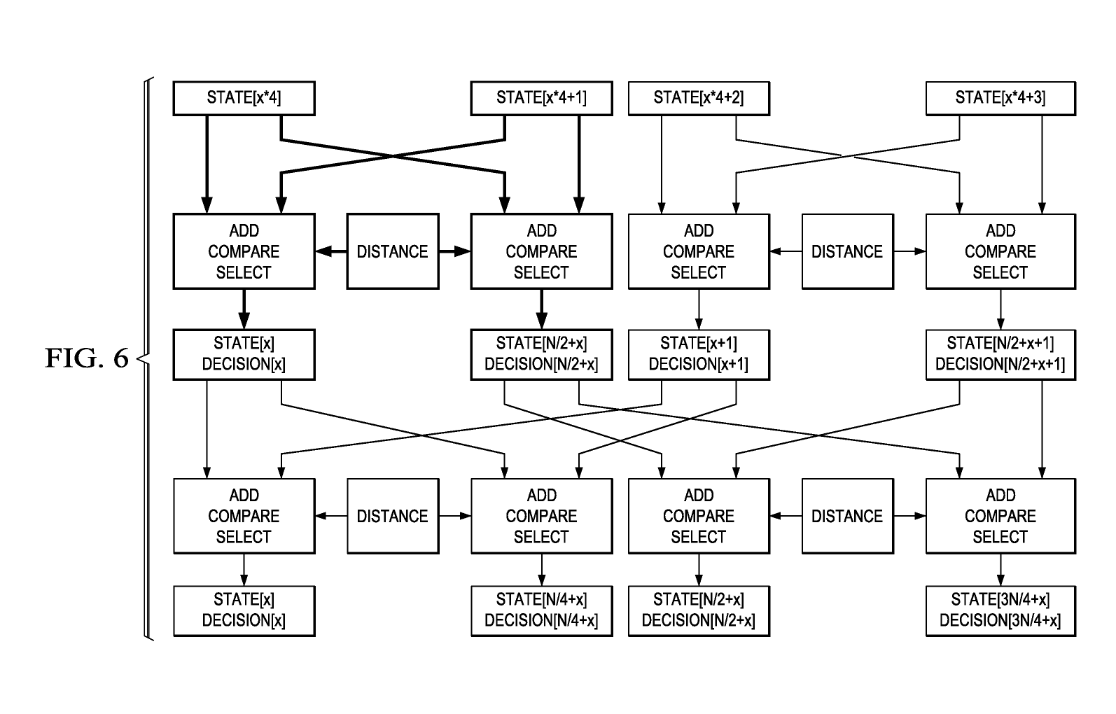

Alternative solutions available today use custom logic in the form or FPGA's, ASIC's or even full custom designs, these typically perform an alternative form of parallelism, by pairing 2 butterflys from 1 stage with two butterflys from the next outer loop, as shown in FIG. 6.

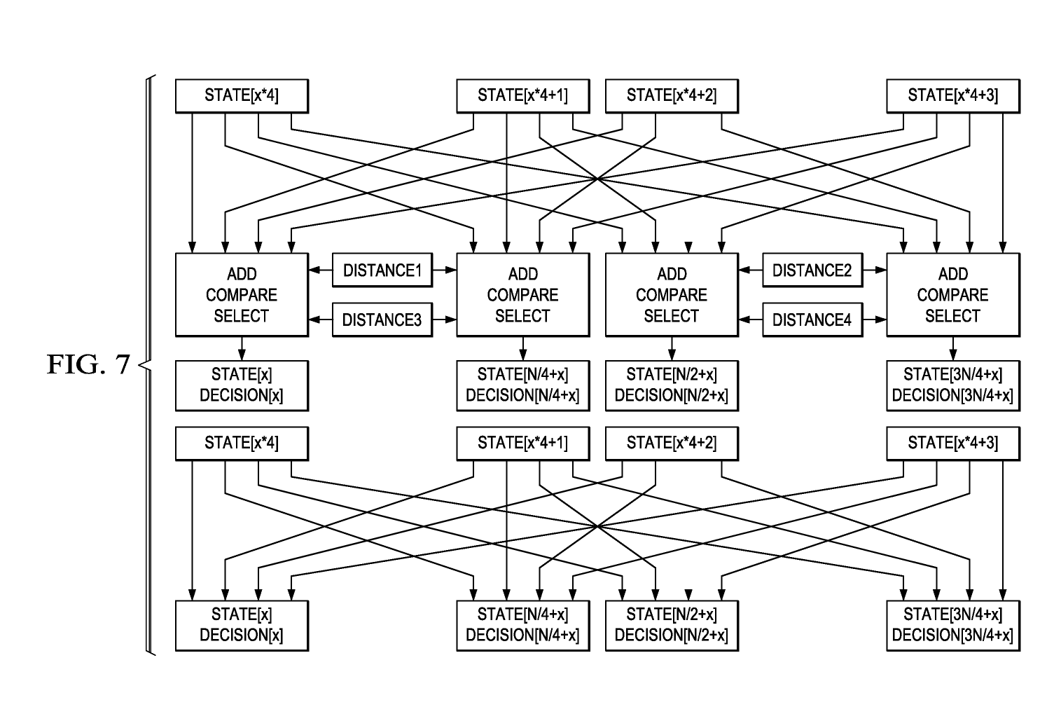

As the decision of the second stage is for all four outputs, it is possible to determine which of the 4 decisions made at the first stage would have lead to the second decision and these decision results can be merged into 4 two bit decisions instead of 8 one-bit decisions. This allows the second feed-back (loop 2) in the first diagram to work on 2 bits at a time halving this loops work. This is also known as a Radix-4 Viterbi Butterfly, and can be simplified to the below left diagram, where the add's and sub's are rearranged to do a 4-way maximum and decision. FIG. 7 is a simplified depiction often used for this stage.

It is possible to further expand this technique to perform radix-8 or radix-16 stages, but as the most common uses of this architecture are to decode length 6 and 8 convolution encoded data the use of radix's higher than radix-4 do not produce good building blocks. Similar to the DSP, radix-4 stages can be paralleled to perform multiple radix-4 stages in parallel, due to the parallel nature of FPGA's and ASIC's, this is a straightforward speed v's area compromise. Where very high speed is needed higher radix-s are used.

Using the radix-4 technique for DSP has in the past proved difficult due to the non-ordered nature of the output (alternatively the input can be.out of order and the output in order). This is solved in an FPGA/ASIC environment by selectively crossing the address lines between write's and reads from memory but this is not allowed in the DSP/CPU world where fixed address lines are de-facto mandatory. The relatively short data word widths of past DSP's have also made this unpromising.

However with proton DSP accelerator as stated earlier, 8 16-bit states can be read in parallel, so the obvious solutions would be either 8 radix-2 stages in parallel which has relatively easy ordering or 2 radix-4 stages in parallel, which obviously has more ordering problems, although it has execution speed advantages.

As in the ASIC/FPGA state-of the art where the decisions of the 2^{nd} radix-2 stage were merged with the decisions of the 1^{st} radix-2 stage to produce 4 2-bit decisions. Hence, the decisions of the 2^{nd} DSP radix-4 stage can be merged with the decisions of the first radix-4 stage. As there are two radix-4's in each instruction, each R4ACD instruction produces 8 2-bit decision paths. By taking these 4 registers as two register-pairs, and inputting them into another instruction a 3^{rd} instruction can be added that converts 4 sets of 8 2-bit paths to 1 set of 16 4-bit paths, which neatly fills a register, which will allow the second trace-back loop to trace-back 4 bits per loop.

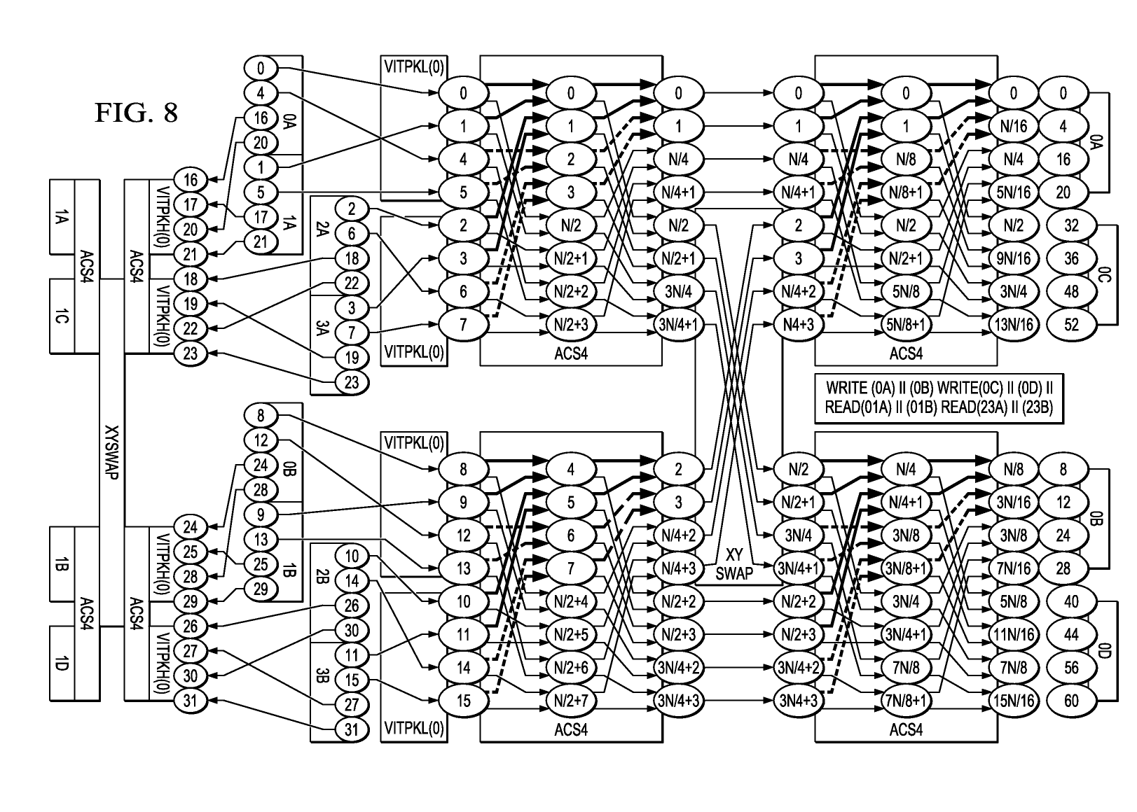

With relatively few additional register swaps and register-interleaving, this register ordering can be used to bring in further inner and outer loops, as shown in FIG. 8, where the instructions are half of a radix-64 solution.

For the first stage two instructions are defined:
REGPAIR _r4acs8h(REGPAIR op1, REG op2, REG op3)
REG _r4acd8h(REGPAIR op1, REG op2, REG op3)

Both of these instructions have the same inputs:
Op1 Contains the previous trellis metrics in the order:
[n,n+1 ,n+4,n+5,n+2,n+3,n+6,n+7]
Op2 Contains the distances for the first stage of the trellis
Op3 Contains the distances for the second stage of the trellis

The output from R4ACS8H is the next trellis stage in the order:
[n,n+m/16,n+m/4,n+5m/16,n+m/2,n+9m/16,n+3m/4,n+13m/16]
   The output from the R4ACD8H is the two bit path needed to get to each of the 8 outputs.

While the foregoing is directed to embodiments of the present invention, other and further embodiments of the invention may be devised without departing from the basic scope thereof, and the scope thereof is determined by the claims that follow.

What is claims is:

1. A digital signal processor for decoding Trellis based channel encoding stages based on radix-4 stages comprising means for rearranging the input and output data in Radix-4 Viterbi decoding to make inter-stage Trellis data movement suitable for use in the digital signal processor.

2. The digital signal processor of claim 1, wherein a Trellis data path is 16-bits.
